(19) United States
(12) Patent Application Publication
(10) Pub. No.: US 2024/0147751 A1
(43) Pub. Date: May 2, 2024

(54) BLUE-LIGHT-EMITTING DEVICE AND MANUFACTURING METHOD THEREFOR, AND DISPLAY APPARATUS

(71) Applicant: BOE Technology Group Co., Ltd., Beijing (CN)

(72) Inventors: Yuqian SUN, Beijing (CN); Dongxu ZHANG, Beijing (CN)

(21) Appl. No.: 18/023,691

(22) PCT Filed: Mar. 3, 2022
(86) PCT No.: PCT/CN2022/079126

§ 371 Date: Feb. 27, 2023

(30) Foreign Application Priority Data
Jun. 23, 2021 (CN) 202110695964.2

(51) Int. Cl. H10K 50/15; H10K 50/16; H10K 50/17; H10K 50/18; H10K 71/12; H10K 85/60

(52) U.S. Cl. CPC H10K 50/15; H10K 50/16; H10K 50/171; H10K 50/181; H10K 71/12; H10K 85/615; H10K 85/631; H10K 85/6572; H10K 85/6574; H10K 2101/30

(57) ABSTRACT

Disclosed in the embodiments of the present disclosure are a blue-light-emitting device and a manufacturing method therefor, and a display apparatus. The blue-light-emitting device comprises a hole transport layer, an electron blocking layer and a light-emitting layer, which are arranged in a stacked manner, wherein the electron blocking layer comprises a first material and a second material, the mobility of the first material is a first mobility, and the mobility of the second material is a second mobility; and the mobility of the hole transport layer is greater than the mobility of the first material, and the mobility of the hole transport layer is greater than the mobility of the second material; and the general structural formula of the material of the hole transport layer is formula (I), the general structural formulae of the first material and the second material are both formula (II), the first material and the second material have different bond energies, and n is equal to 0 or 1.

### CROSS REFERENCE TO RELATED APPLICATIONS

This application is a US National Stage of International Application No. PCT/CN2022/079126, filed on Mar. 3, 2022, which claims the priority of Chinese patent application No. 202110695964.2, filed with the China National Intellectual Property Administration on Jun. 23, 2021 and entitled “BLUE-LIGHT-EMITTING DEVICE AND MANUFACTURING METHOD THEREFOR, AND DISPLAY APPARATUS”, the entire contents of which are incorporated herein by reference.

### FIELD

The disclosure relates to the field of display technology, in particular to a blue-light-emitting device and a manufacturing method therefor, and a display apparatus.

### BACKGROUND

An organic light-emitting diode display device has been widely used due to the advantages of wide color gamut, solid-state luminescence, the capability of being made into a flexible display device, and the like.

Typically, a pixel unit of the organic light-emitting diode display device includes red organic light-emitting diodes, blue organic light-emitting diodes, and green organic light-emitting diodes.

### SUMMARY

An embodiment of the disclosure provides a blue-light-emitting device, including a hole transport layer, an electron blocking layer and a light-emitting layer which are in stack. The electron blocking layer includes a first material and a second material, the mobility of the first material is a first mobility, and the mobility of the second material is a second mobility; and the mobility of the hole transport layer is greater than the first mobility of the first material, and the mobility of the hole transport layer is greater than the second mobility of the second material. A general structural formula of a material of the hole transport layer is

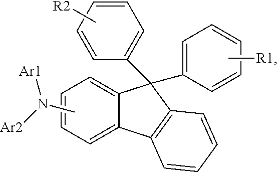

general structural formulae of the first material and the second material are both

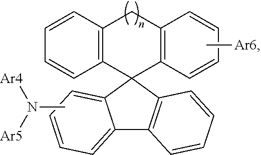

and the first material and the second material have different bond energies. Here Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, acylamino with 6 to 39 carbon atoms, cycloalkyl with 3 to 39 carbon atoms, heterocycloalkyl with 3 to 39 carbon atoms, and alkylsilyl with 1 to 39 carbon atoms. R1 and R2 are independently selected from hydrogen and alkyl with 1 to 39 carbon atoms; and n is 0 or 1.

In some embodiments, in the above blue-light-emitting device provided by the embodiment of the disclosure, the electron blocking layer is of a single-layer structure, and a material of the electron blocking layer is a mixed material of the first material and the second material.

In some embodiments, in the above blue-light-emitting device provided by the embodiment of the disclosure, the electron blocking layer includes a first electron blocking layer close to the hole transport layer, and a second electron blocking layer located between the first electron blocking layer and the light-emitting layer. A material of the first electron blocking layer is the first material and a material of the second electron blocking layer is the second material. The first mobility is greater than the second mobility; and the bond energy of the second material is greater than that of the first material.

In some embodiments, in the above blue-light-emitting device provided by the embodiment of the disclosure, a ratio of the mobility of the hole transport layer to the first mobility is greater than 10, a ratio of the mobility of the hole transport layer to the second mobility is greater than 10, and a ratio of the first mobility to the second mobility is greater than 1.

In some embodiments, in the above blue-light-emitting device provided by the embodiment of the disclosure, the mobility of the hole transport layer is 1×10⁻⁶-9.9×10⁻³, the first mobility is 1×10⁻⁸-1×10⁻⁴, and the second mobility is 1×10⁻⁹-1×10⁻⁵.

In some embodiments, in the above blue-light-emitting device provided by the embodiment of the disclosure, a bond energy for positive charge of the first material is greater than or equal to 2.8 eV, and a bond energy for negative charge of the first material is greater than or equal to 0.8 eV; and

a bond energy for positive charge of the second material is greater than or equal to 3 eV and a bond energy for negative charge of the second material is greater than or equal to 1 eV.

In some embodiments, in the above blue-light-emitting device provided by the embodiment of the disclosure, the HOMO energy level of the hole transport layer is −5.6 eV to −5.2 eV.

In some embodiments, in the above blue-light-emitting device provided by the embodiment of the disclosure, the material of the hole transport layer has a molecular weight greater than or equal to 550.

In some embodiments, in the above blue-light-emitting device provided by the embodiment of the disclosure, a difference between the HOMO energy level of the first material and the HOMO energy level of the second material is less than or equal to 0.2 eV.

In some embodiments, in the above blue-light-emitting device provided by the embodiment of the disclosure, the first material and the second material each have a molecular weight greater than or equal to 450.

In some embodiments, in the above blue-light-emitting device provided by the embodiment of the disclosure, the material of the hole transport layer is

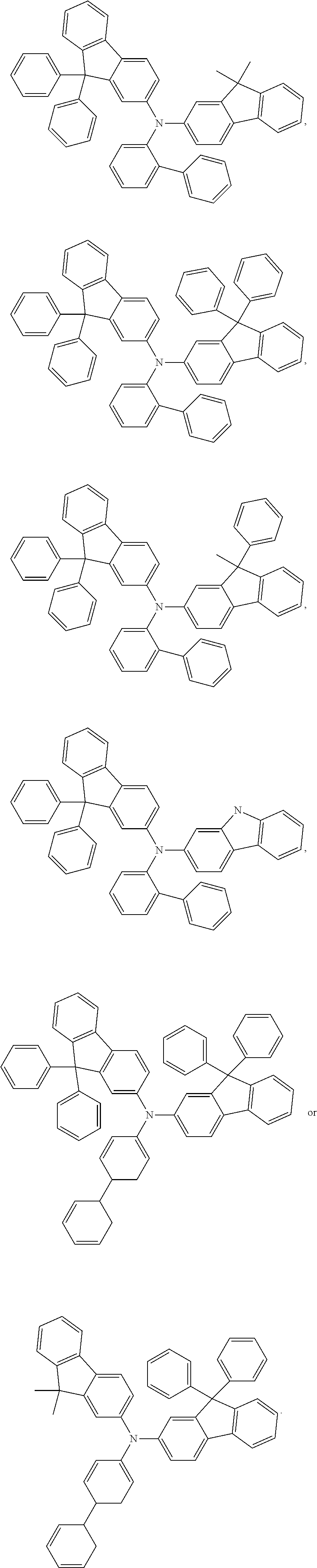

In some embodiments, in the above blue-light-emitting device provided by the embodiment of the disclosure, the first material and the second material are isomers of each other.

In some embodiments, in the above blue-light-emitting device provided by the embodiment of the disclosure, the structure of the first material is

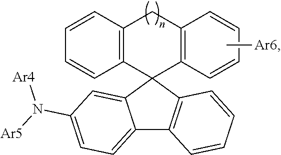

and the structure of the second material is

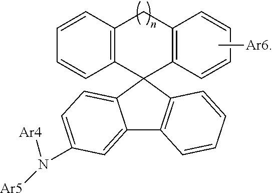

In some embodiments, in the above blue-light-emitting device provided by the embodiment of the disclosure, the structure of the first material is

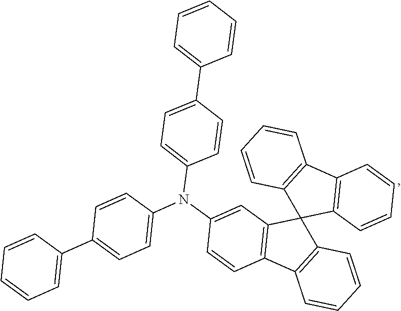 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

and the structure of the second material is

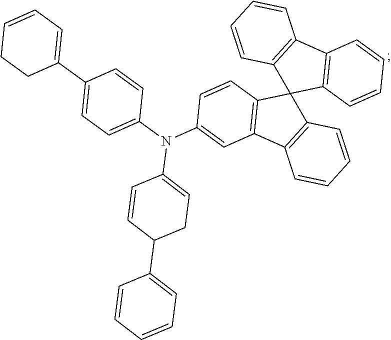 [SMILES: C1=CCCC(c2ccc(N(C3=CCC(c4ccccc4)C=C3)c3ccc4c(c3)-c3ccccc3C43c4ccccc4-c4ccccc43)cc2)=C1]

or the structure of the first material is

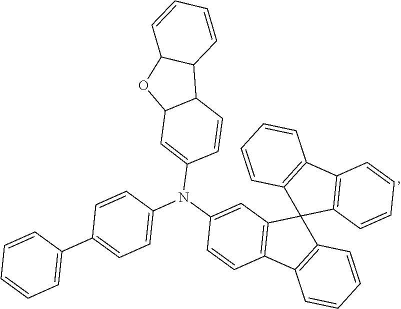 [SMILES: C1=CC2OC3C=C(N(c4ccc(-c5ccccc5)cc4)c4ccc5c(c4)C4(c6ccccc6-c6ccccc64)c4ccccc4-5)C=CC3C2C=C1]

and the structure of the second material is

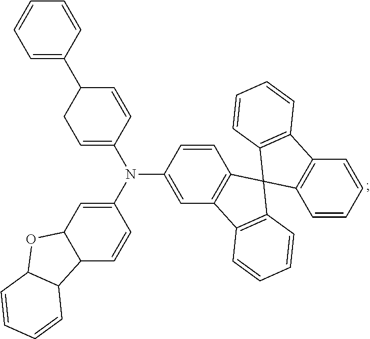 [SMILES: C1=CC2OC3C=C(N(C4=CCC(c5ccccc5)C=C4)c4ccc5c(c4)-c4ccccc4C54c5ccccc5-c5ccccc54)C=CC3C2C=C1]

or the structure of the first material is

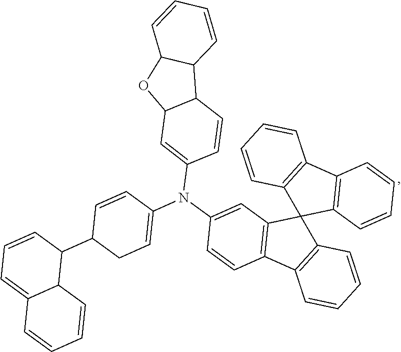 [SMILES: C1=CC2=CC=CC(C3C=CC(N(C4=CC5OC6C=CC=CC6C5C=C4)c4ccc5c(c4)C4(c6ccccc6-c6ccccc64)c4ccccc4-5)=CC3)C2C=C1]

and the structure of the second material is

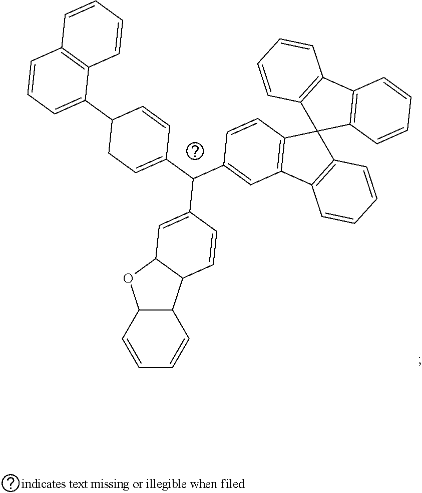 [SMILES: C1=CC2OC3C=C(C(C4=CCC(c5cccc6ccccc56)C=C4)c4ccc5c(c4)-c4ccccc4C54c5ccccc5-c5ccccc54)C=CC3C2C=C1]

or the structure of the first material is

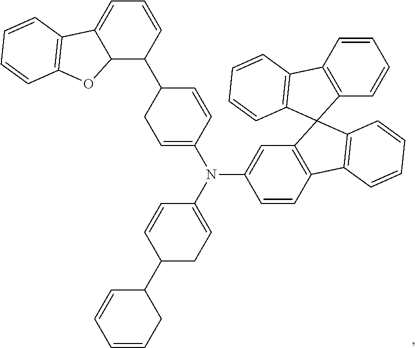 [SMILES: C1=CCC(C2C=CC(N(C3=CCC(C4C=CC=C5c6ccccc6OC54)C=C3)c3ccc4c(c3)C3(c5ccccc5-c5ccccc53)c3ccccc3-4)=CC2)C=C1]

and the structure of the second material is

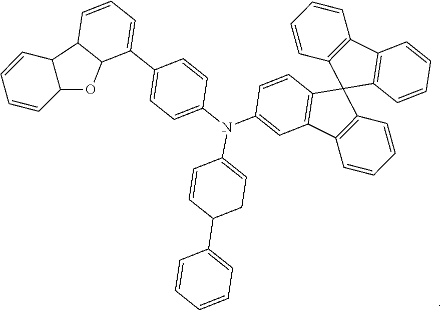 [SMILES: C1=CC2OC3C(c4ccc(N(C5=CCC(c6ccccc6)C=C5)c5ccc6c(c5)-c5ccccc5C65c6ccccc6-c6ccccc65)cc4)=CC=CC3C2C=C1]

In some embodiments, the above blue-light-emitting device provided by the embodiment of the disclosure further includes an anode disposed on the side of the hole transport layer facing away from the light-emitting layer, a hole blocking layer disposed on the side of the light-emitting layer facing away from the hole transport layer, an electron transport layer disposed on the side of the hole blocking layer facing away from the hole transport layer, an electron injection layer disposed on the side of the electron transport layer facing away from the hole transport layer, and a cathode disposed on the side of the electron injection layer facing away from the hole transport layer.

Accordingly, an embodiment of the disclosure also provides a display apparatus, including any one of the blue-light-emitting devices described above.

Accordingly, an embodiment of the disclosure also provides a manufacturing method for any one of the blue-light-emitting devices described above, including: forming a hole transport layer, an electron blocking layer, and a light-emitting layer which are in stack. The electron blocking layer includes a first material and a second material, the mobility of the first material is a first mobility, and the mobility of the second material is a second mobility; and the mobility of the hole transport layer is greater than the mobility of the first material, and the mobility of the hole transport layer is greater than the mobility of the second material. A general structural formula of a material of the hole transport layer is

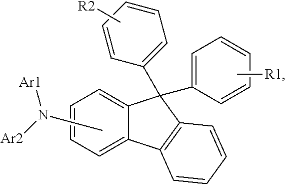

general structural formulae of the first material and the second material are both

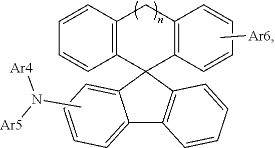

and the first material and the second material have different bond energies. Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, acylamino with 6 to 39 carbon atoms, cycloalkyl with 3 to 39 carbon atoms, heterocycloalkyl with 3 to 39 carbon atoms, and alkylsilyl with 1 to 39 carbon atoms; R1 and R2 are independently selected from hydrogen and alkyl with 1 to 39 carbon atoms; and n is 0 or 1.

In some embodiments, in the above manufacturing method provided by the embodiment of the disclosure, forming the electron blocking layer specifically includes: mixing the first material and the second material; and forming the electron blocking layer between the hole transport layer and the light-emitting layer by using a mixture of the first material and the second material.

In some embodiments, in the above manufacturing method provided by the embodiment of the disclosure, forming the electron blocking layer specifically includes: forming a first electron blocking layer close to the hole transport layer by using the first material, and forming a second electron blocking layer between the first electron blocking layer and the light-emitting layer by using the second material.

### BRIEF DESCRIPTION OF THE DRAWINGS

FIGS. 1A-1C are structures of materials of three hole transport layers in the related art.

FIGS. 1D and 1E are structures of materials of two electron blocking layers in the related art.

FIG. 2 is a schematic structural diagram of a blue-light-emitting device according to an embodiment of the disclosure.

FIG. 3 is a schematic structural diagram of another blue-light-emitting device according to an embodiment of the disclosure.

FIG. 4 shows curves illustrating carrier mobility—electric field intensity changes for first materials and second materials according to the embodiments of the disclosure.

FIG. 5 is a schematic structural diagram of another blue-light-emitting device according to an embodiment of the disclosure.

FIG. 6 shows a lifetime change curve corresponding to embodiments according to the embodiments of the disclosure.

FIG. 7 is a schematic flowchart of a manufacturing method for an electron blocking layer according to an embodiment of the disclosure.

### DETAILED DESCRIPTION

In order to make objectives, technical solutions and advantages of the embodiments of the disclosure clearer, the technical solutions of the embodiments of the disclosure are described clearly and completely below with reference to the drawings of the embodiments of the disclosure. Apparently, the described embodiments are some, not all, of the embodiments of the disclosure. The embodiments in the disclosure and features in the embodiments may be mutually combined under the condition of no conflict. Based on the described embodiments of the disclosure, all other embodiments obtained those of ordinary skill in the art without creative work fall within the protection scope of the disclosure.

Unless otherwise defined, technical or scientific terms used in the disclosure shall have the ordinary meaning as understood by those of ordinary skill in the art to which the disclosure belongs. Similar words such as “including” or “comprising” used in the disclosure mean that elements or objects appearing in front of the word cover elements or objects listed behind the word and equivalents thereof, without excluding other elements or objects. “Connection” or “connected” and other similar words may include electrical connection, direct or indirect, instead of being limited to physical or mechanical connection. “Inner”, “outer”, “upper”, “lower”, etc. are only used to indicate a relative positional relationship, and when an absolute position of a described object changes, the relative positional relationship may also change accordingly.

It should be noted that sizes and shapes of all figures in the drawings do not reflect a true scale and are only intended to illustrate the contents of the disclosure. Same or similar reference signs throughout denote same or similar elements or elements with same or similar functions.

An Organic Light Emitting Display (OLED) has the advantages of wide viewing angle, almost infinitely high contrast ratio, low power consumption, extremely high response speed, etc., and is therefore widely applied to high-end displays. With the increasing number of products and the continuous development of products, customers have higher and higher requirements for product resolution and lower and lower requirements for power consumption. It is necessary to develop devices with high efficiency, low voltage and long lifetime.

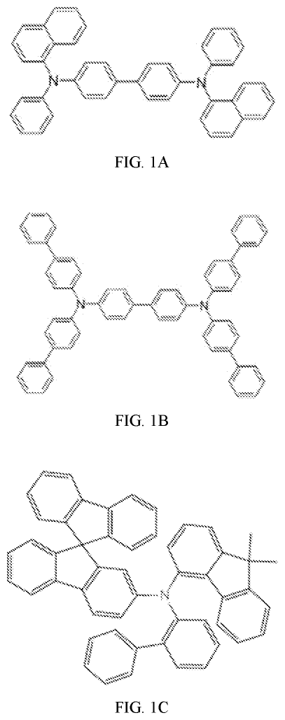

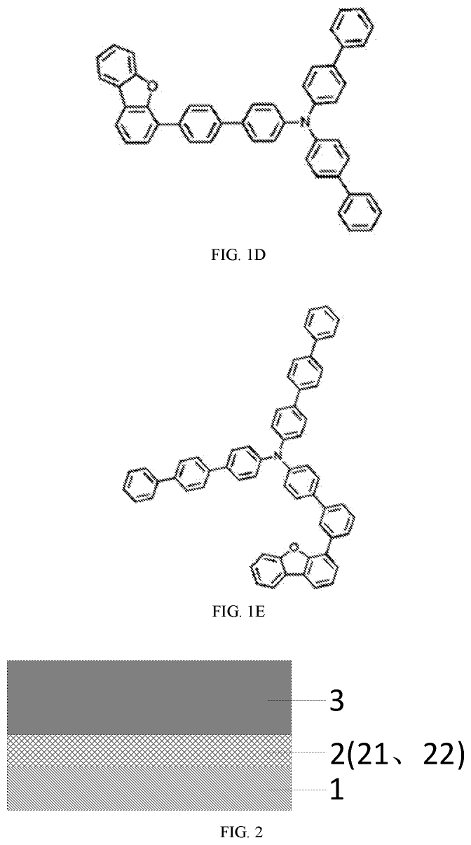

Currently, the OLED device essentially consists of an anode, a hole transport layer, an electron blocking layer, a light-emitting layer, a hole blocking layer, an electron transport layer and a cathode. In order to obtain devices with high efficiency, at present, commonly used materials of both the hole transport layer and the electron blocking layer are arylamine materials with higher hole mobility. The arylamine materials have poor stability, for example, as shown in FIGS. 1A-1E, here FIGS. 1A-1C are structures of materials of common three hole transport layers used in the related art, and FIGS. 1D and 1E are structures of materials of common two electron blocking layers used in the related art. In order to obtain a blue-light-emitting device with high efficiency, a certain amount of lifetime will be lost, and simultaneously increasing the efficiency and lifetime of the blue-light-emitting device has become an urgent problem to be solved.

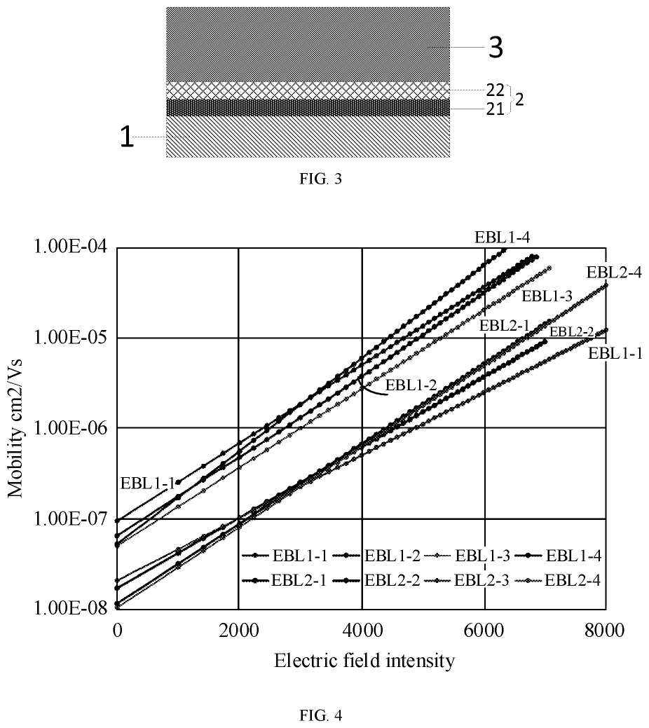

In view of this, an embodiment of the disclosure provides a blue-light-emitting device, as shown in FIGS. 2 and 3, including a hole transport layer 1, an electron blocking layer 2 and a light-emitting layer 3 which are in stack. The electron blocking layer 1 includes a first material and a second material, the mobility of the first material is a first mobility and the mobility of the second material is a second mobility μ2. The mobility of the hole transport layer is greater than the first mobility μ1 of the first material, and the mobility of the hole transport layer is greater than the second mobility μ2 of the second material.

A general structural formula of a material of the hole transport layer 1 is

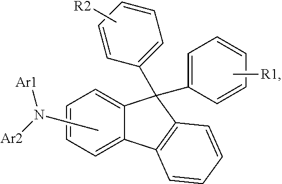

general structural formulae of the first material and the second material both

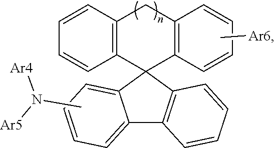

are and the first material and the second material have different bond energies.

Here, Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, acylamino with 6 to 39 carbon atoms, cycloalkyl with 3 to 39 carbon atoms, heterocycloalkyl with 3 to 39 carbon atoms, and alkylsilyl with 1 to 39 carbon atoms.

R1 and R2 are independently selected from hydrogen and alkyl with 1 to 39 carbon atoms.

Here, n is 0 or 1, and in particular, n being 0 represents a bond.

According to the above blue-light-emitting device provided by the embodiment of the disclosure, due to the device structure designed according to the embodiments of the disclosure and the material structure characteristics and mobility rules of the hole transport layer 1 and the electron blocking layer 2, performance of the blue-light-emitting device can be greatly improved, and finally the efficiency and lifetime of the blue-light-emitting device are simultaneously improved, and the power consumption is reduced.

In specific implementation, in the above blue-light-emitting device provided by the embodiment of the disclosure, as shown in FIG. 2, the electron blocking layer 2 may be of a single-layer structure, and a material of the electron blocking layer 2 is a mixed material of the first material and the second material. In the embodiments of the disclosure, the luminous efficiency and lifetime of the blue-light-emitting device can be improved, and the power consumption can be reduced by rationally designing the mobility of the first material and the mobility of the second material.

In specific implementation, in the above blue-light-emitting device provided by the embodiment of the disclosure, as shown in FIG. 3, the electron blocking layer 2 may include a first electron blocking layer 21 close to the hole transport layer 1, and a second electron blocking layer 22 between the first electron blocking layer 21 and the light-emitting layer 3. A material of the first electron blocking layer 21 is the first material and a material of the second electron blocking layer 22 is the second material.

The first mobility μ1 is greater than the second mobility μ2, such that the mobility of the hole transport layer 1, the mobility of the first electron blocking layer 21 and the mobility of the second electron blocking layer 22 gradually decrease, which is beneficial to the transport of holes from the hole transport layer 1 to the light-emitting layer 3, increasing the carrier injection balance of the device, thereby improving the luminous efficiency and lifetime of the device, and reducing the power consumption of the device.

The bond energy of the second material is greater than that of the first material. By selecting the first material and the second material which have suitable bond energies, the stability of the electron blocking layer can be ensured on one hand, and the performance of the device can be improved on the other hand.

Further, in the above blue-light-emitting device provided by the embodiment of the disclosure, as shown in FIGS. 2 and 3, a ratio of the mobility (μ3) of the hole transport layer 1 to the first mobility (μ1) is greater than 10, a ratio of the mobility (μ3) of the hole transport layer to the second mobility (μ2) is greater than 10, and a ratio of the first mobility (μ1) to the second mobility (μ2) is greater than 1, i.e. the mobility of the hole transport layer 1, the mobility of the first electron blocking layer 21 and the mobility of the second electron blocking layer 22 gradually decrease, which is beneficial to the transport of holes from the hole transport layer 1 to the light-emitting layer 3, increasing the carrier injection balance of the device, thereby improving the luminous efficiency and lifetime of the device, and reducing the power consumption of the device.

Further, in the above blue-light-emitting device provided by the embodiment of the disclosure, as shown in FIG. 3, the mobility of the hole transport layer 1 may be 1×10⁻⁶ cm²/V·s-9.9×10⁻³ cm²/V·s, the first mobility may be 1×10⁻⁸ cm²/V·s-1×10⁻⁴ cm²/V·s, and the second mobility may be 1×10⁻⁹ cm²/V·s-1×10⁻⁵ cm²/V·s.

It should be noted that the aforementioned bond energy (BDE) refers to the minimum energy required for breaking a bond, and the bond energy includes a bond energy for a positive charge associated with its stability and a bond energy for a negative charge associated with its stability.

Further, in order to ensure the stability of the first electron blocking layer and the stability of the second electron blocking layer, in the above blue-light-emitting device provided by the embodiment of the disclosure, a bond energy for positive charge of the first material is greater than or equal to 2.8 eV, and a bond energy for negative charge of the first material is greater than or equal to 0.8 eV.

A bond energy for positive charge of the second material is greater than or equal to 3 eV, and a bond energy for negative charge of the second material is greater than or equal to 1 eV. In this way, the stability of the first electron blocking layer and the stability of the second electron blocking layer are good, and the first electron blocking layer and the second electron blocking layer provided by the embodiment of the disclosure can improve the luminous efficiency of the device and prolong the lifetime of the device, and the like compared with the arylamine materials that have poor stability used in the related art.

Further, in the above blue-light-emitting device provided by the embodiment of the disclosure, as shown in FIGS. 2 and 3, the HOMO energy level of the hole transport layer 1 may be −5.6 eV to −5.2 eV, which is close to the energy level of the light-emitting layer 3, facilitating hole injection.

It should be noted that HOMO is short for and refers to a highest energy occupied molecular orbital.

Further, in order to ensure the stability of the hole transport layer, in the above blue-light-emitting device provided by the embodiment of the disclosure, as shown in FIGS. 2 and 3, the material of the hole transport layer 1 has a molecular weight greater than or equal to 550.

Further, in order to further improve the hole transport efficiency, in the above blue-light-emitting device provided by the embodiment of the disclosure, as shown in FIGS. 2 and 3, a difference between the HOMO energy level of the first material (the first electron blocking layer 21) and the HOMO energy level of the second material (the second electron blocking layer 22) is less than or equal to 0.2 eV.

Further, in order to ensure the stability of the electron blocking layer, in the above blue-light-emitting device provided by the embodiment of the disclosure, as shown in FIGS. 2 and 3, the first material (the first electron blocking layer 21) and the second material (the second electron blocking layer 22) each have a molecular weight greater than or equal to 450.

Further, in the above blue-light-emitting device provided by the embodiment of the disclosure, as shown in FIGS. 2 and 3, the material of the hole transport layer 1 may be, but is not limited to,

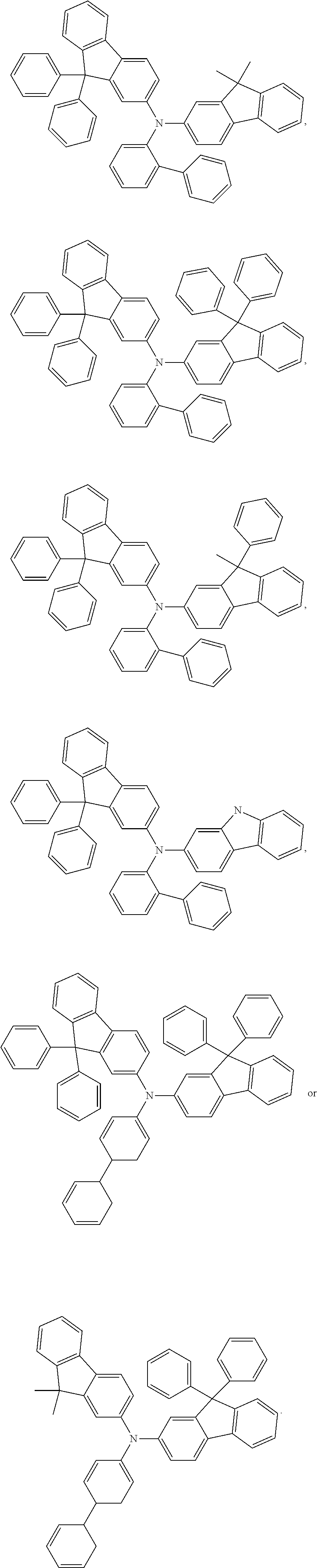

It should be noted that the embodiment of the disclosure merely lists the above six material structures of the hole transport layer 1 as examples, a material is within the scope of protection of the embodiments of the disclosure, as long as the material of the hole transport layer 1 conforms to the general formula

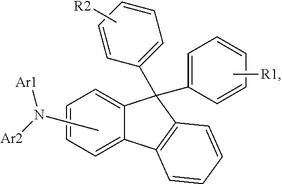

Further, in the above blue-light-emitting device provided by the embodiment of the disclosure, as shown in FIGS. 2 and 3, the first material (the first electron blocking layer 21) and the second material (the second electron blocking layer 22) may be isomers.

Further, in the above blue-light-emitting device provided by the embodiment of the disclosure, as shown in FIGS. 2 and 3, the structure of the first material (the first electron blocking layer 21) may be

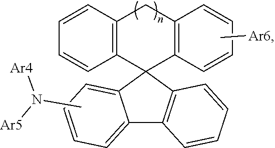

the structure of the second material (the second electron blocking layer 22) may be

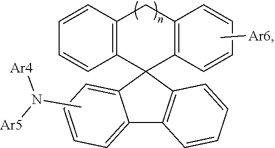

i.e., in the first material, the 2-position of a spirocyclic ring (a benzene ring) is substituted, and in the second material, the 3-position of a spirocyclic ring (a benzene ring) is substituted.

Further, in the above blue-light-emitting device provided by the embodiment of the disclosure, as shown in FIGS. 2 and 3, the structure of the first material (the first electron blocking layer 21) may be

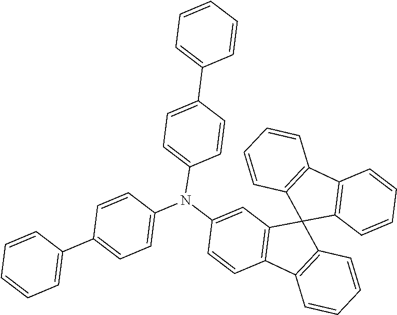 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

(EBL1-1 for short), and the structure of the second material (the second electron blocking layer 22) may be

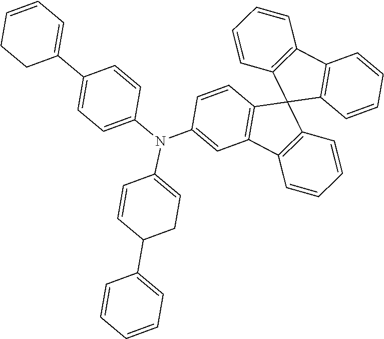 [SMILES: C1=CCCC(c2ccc(N(C3=CCC(c4ccccc4)C=C3)c3ccc4c(c3)-c3ccccc3C43c4ccccc4-c4ccccc43)cc2)=C1]

(EBL2-1 for short).

Alternatively, the structure of the first material (the first electron blocking layer 21) may be

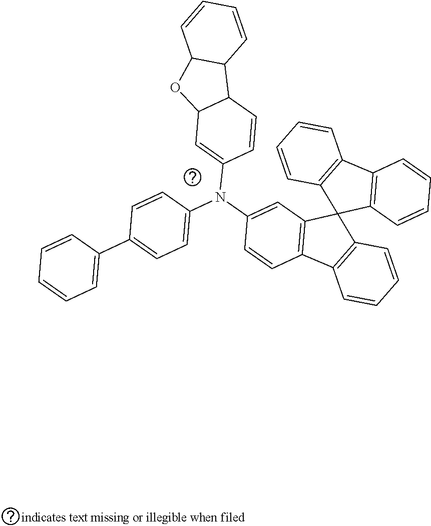 [SMILES: C1=CC2OC3C=C(N(c4ccc(-c5ccccc5)cc4)c4ccc5c(c4)C4(c6ccccc6-c6ccccc64)c4ccccc4-5)C=CC3C2C=C1]

(EBL1-2 for short), and the structure of the second material (the second electron blocking layer 22) may be

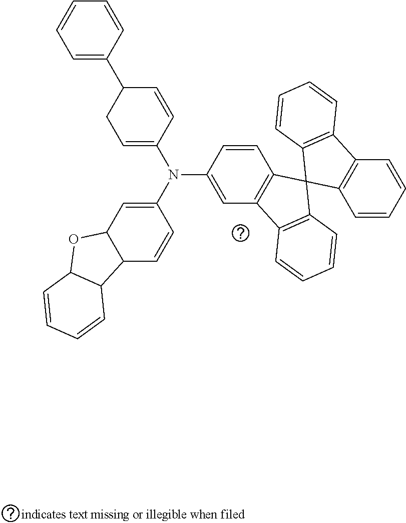 [SMILES: C1=CC2OC3C=C(N(C4=CCC(c5ccccc5)C=C4)c4ccc5c(c4)-c4ccccc4C54c5ccccc5-c5ccccc54)C=CC3C2C=C1]

(EBL2-2 for short).

Alternatively, the structure of the first material (the first electron blocking layer 21) may

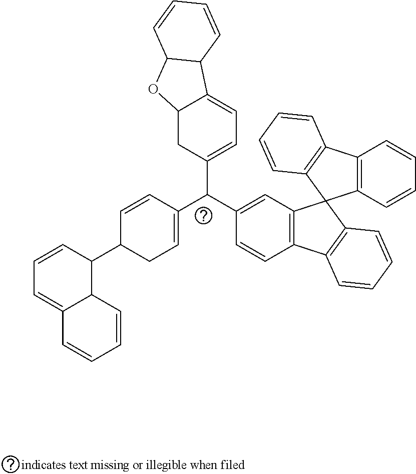 [SMILES: C1=CC2=CC=CC(C3C=CC(C(C4=CC=C5C(C4)OC4C=CC=CC54)c4ccc5c(c4)C4(c6ccccc6-c6ccccc64)c4ccccc4-5)=CC3)C2C=C1]

(EBL1-3 for short), and the structure of the second material (the second electron blocking layer 22) may be

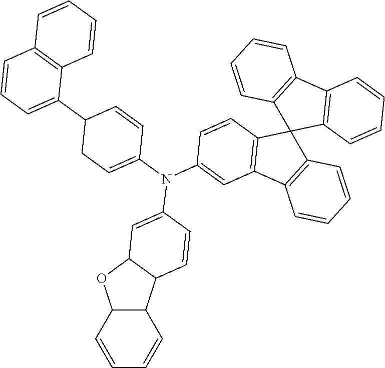 [SMILES: C1=CC2OC3C=C(N(C4=CCC(c5cccc6ccccc56)C=C4)c4ccc5c(c4)-c4ccccc4C54c5ccccc5-c5ccccc54)C=CC3C2C=C1]

(EBL2-3 for short).

Alternatively, the structure of the first material (the first electron blocking layer 21) may be

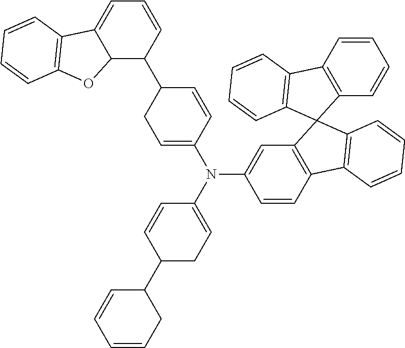 [SMILES: C1=CCC(C2C=CC(N(C3=CCC(C4C=CC=C5c6ccccc6OC54)C=C3)c3ccc4c(c3)C3(c5ccccc5-c5ccccc53)c3ccccc3-4)=CC2)C=C1]

(EBL1-4 for short), and the structure of the second material (the second electron blocking layer 22) may be

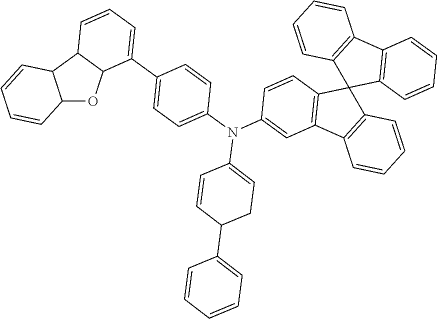 [SMILES: C1=CC2OC3C(c4ccc(N(C5=CCC(c6ccccc6)C=C5)c5ccc6c(c5)-c5ccccc5C65c6ccccc6-c6ccccc65)cc4)=CC=CC3C2C=C1]

(EBL2-4 for short).

It should be noted that the embodiment of the disclosure merely lists structures of four pairs of the first materials and the second materials as examples, a first material and a second material are within the protection scope of the embodiments of the disclosure, as long as the first material and the second material conform to the general formula

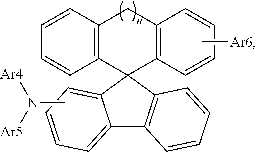

and the first material and the second material are isomers.

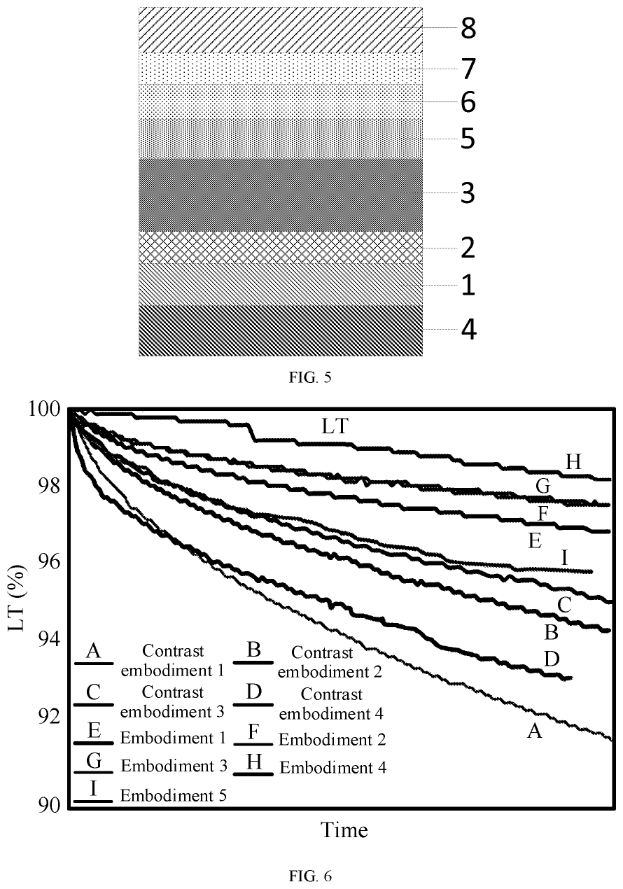

Specifically, as shown in FIG. 4, FIG. 4 shows curves of an electric field intensity-mobility change for the first materials and the second materials described above.

In particular, based on the device structure in FIG. 2 or FIG. 3 according to the embodiment of the disclosure, and selecting the material of the hole transport layer, the first material, and the second material provided above, and in combination with specific mobility laws and bond energy laws, the performance of the blue-light-emitting device can be greatly improved, and finally the efficiency and lifetime of the blue-light-emitting device are simultaneously improved, and the power consumption is reduced.

Further, the above blue-light-emitting device provided by the embodiment of the disclosure, as shown in FIG. 5, further includes an anode 4 disposed on the side of the hole transport layer 1 facing away from the light-emitting layer 3, a hole blocking layer 5 disposed on the side of the light-emitting layer 3 facing away from the hole transport layer 1, an electron transport layer 6 disposed on the side of the hole blocking layer 5 facing away from the hole transport layer 1, an electron injection layer 7 disposed on the side of the electron transport layer 6 facing away from the hole transport layer 1, and a cathode 8 disposed on the side of the electron injection layer 7 facing away from the hole transport layer 1. In particular, the anode 4, the hole blocking layer 5, the electron transport layer 6, the electron injection layer 7 and the cathode 8 are the same as those in the related art, and are not described in detail here.

In specific implementation, the blue-light-emitting device shown in FIG. 5 may further include a hole injection layer between the anode 4 and the hole transport layer 1, and the hole injection layer is the same as that in the related art, and is not described in detail here.

It should be noted that the light-emitting device can be in either a top-emitting structure or a bottom-emitting structure. The difference between the top-emitting structure and the bottom-emitting structure is whether the light is emitted through a substrate or emitted in a direction facing away from the substrate. For the bottom-emitting structure, the light is emitted through the substrate; and for the top-emitting structure, the light is emitted in the direction facing away from the substrate.

It should be noted that the structure of the light-emitting device may be a conventional structure or an inverted structure. The difference between the conventional structure and the inverted structure is that the film layers are manufactured in different orders. Specifically, for the conventional structure, a cathode, an electron injection layer, an electron transport layer, a hole blocking layer, a light-emitting layer, an electron blocking layer, a hole transport layer, and an anode are sequentially formed on a substrate in that order; while for the inverted structure, an anode, a hole transport layer, an electron blocking layer, a light-emitting layer, a hole blocking layer, an electron transport layer, an electron injection layer, and a cathode are sequentially formed on a substrate in that order.

The blue-light-emitting device provided by the embodiment of the disclosure may be of a conventional bottom-emitting structure, a conventional top-emitting structure, an inverted top-emitting structure or an inverted bottom-emitting structure, which is not limited.

The performance (the efficiency, lifetime and voltage) of the blue-light-emitting device structure provided by the embodiment of the disclosure (FIG. 5) and the performance (the efficiency, lifetime and voltage) of the blue-light-emitting device structure in the related art are compared below through experiments.

Blue-light-emitting device structures in the related art are described as follows.

Contrast embodiment 1: a contrast device 1 is manufactured by selecting a material shown in FIG. 1A (which denotes as NPB for short) for a hole transport layer, and selecting

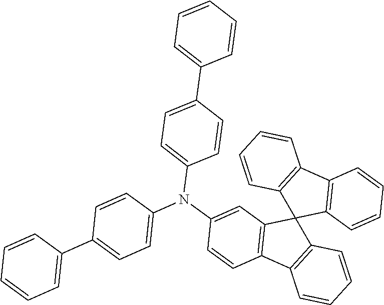 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

(EBL1-1 for short) for an electron blocking layer.

Contrast embodiment 2: a contrast device 2 is manufactured by selecting a material shown in FIG. 1A (which denotes as NPB for short) for a hole transport layer, and selecting

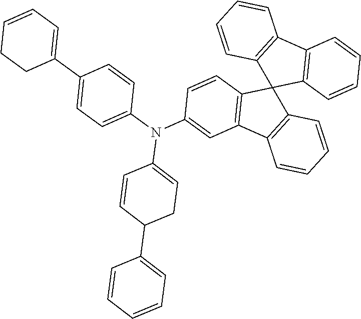 [SMILES: C1=CCCC(c2ccc(N(C3=CCC(c4ccccc4)C=C3)c3ccc4c(c3)-c3ccccc3C43c4ccccc4-c4ccccc43)cc2)=C1]

(EBL2-1 for short) for an electron blocking layer.

Contrast embodiment 3: a contrast device 3 is manufactured by selecting a material shown in FIG. 1C (which is referred to as Contrast HT for short) for a hole transport layer, and sequentially selecting EBL1-1 (close to the hole transport layer) and EBL2-1 (facing away from the hole transport layer) described above for an electron blocking layer.

Contrast embodiment 4: a contrast device 4 is manufactured by selecting

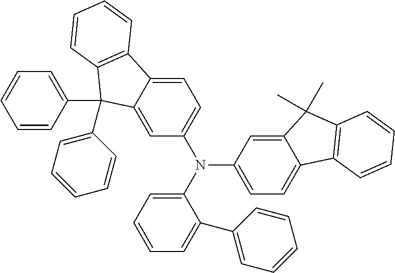 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

(which denotes as HT-1 for short) for a hole transport layer, and sequentially selecting EBL2-1 (close to the hole transport layer) and EBL1-1 (facing away from the hole transport layer) described above for an electron blocking layer.

Blue-light-emitting device structure in the disclosure is described as follows.

Embodiment 1: a device 1 is manufactured by selecting

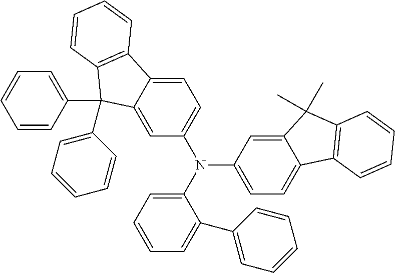 [SMILES: CC1(C)c2ccccc2-c2ccc(N(c3ccc4c(c3)C(c3ccccc3)(c3ccccc3)c3ccccc3-4)c3ccccc3-c3ccccc3)cc21]

(which is referred to as HT-1 for short) for a hole transport layer, and sequentially selecting EBL1-1 (close to the hole transport layer) and EBL2-1 (facing away from the hole transport layer) described above for an electron blocking layer.

Embodiment 2: a device 2 is manufactured by selecting HT-1 described above for a hole transport layer, and sequentially selecting

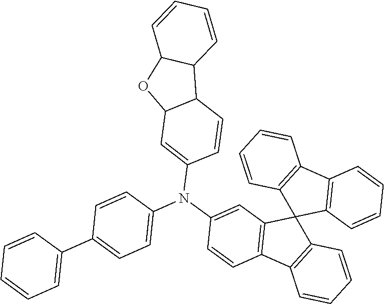 [SMILES: C1=CC2OC3C=C(N(c4ccc(-c5ccccc5)cc4)c4ccc5c(c4)C4(c6ccccc6-c6ccccc64)c4ccccc4-5)C=CC3C2C=C1]

(EBL1-2 for short, close to the hole transport layer) and

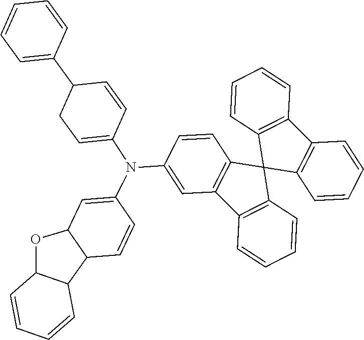 [SMILES: C1=CC2OC3C=C(N(C4=CCC(c5ccccc5)C=C4)c4ccc5c(c4)-c4ccccc4C54c5ccccc5-c5ccccc54)C=CC3C2C=C1]

(EBL2-2 for short, facing away from the hole transport layer) for an electron blocking layer.

Embodiment 3: a device 3 is manufactured by selecting HT-1 described above for a hole transport layer, and sequentially selecting

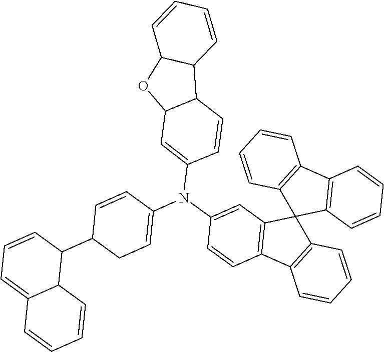 [SMILES: C1=CC2=CC=CC(C3C=CC(N(C4=CC5OC6C=CC=CC6C5C=C4)c4ccc5c(c4)C4(c6ccccc6-c6ccccc64)c4ccccc4-5)=CC3)C2C=C1]

(EBL1-3 for short, close to the hole transport layer) and

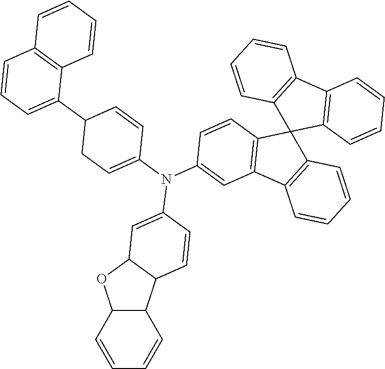 [SMILES: C1=CC2OC3C=C(N(C4=CCC(c5cccc6ccccc56)C=C4)c4ccc5c(c4)-c4ccccc4C54c5ccccc5-c5ccccc54)C=CC3C2C=C1]

(EBL2-3 for short, facing away from the hole transport layer) for an electron blocking layer.

Embodiment 4: a device 4 is manufactured by selecting

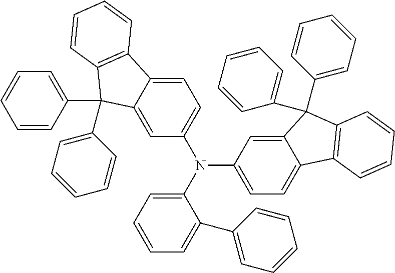 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

(HT-2 for short) for a hole transport layer, and sequentially selecting EBL1-1 (close to the hole transport layer) and EBL2-1 (facing away from the hole transport layer) described above for an electron blocking layer.

Embodiment 5: a device 5 is manufactured by selecting HT-1 described above for a hole transport layer, and selecting EBL1-2 and EBL2-2 described above which are premixed in a ratio of 1:1 for an electron blocking layer.

TABLE 1
Energy level parameters for the above
materials used in the disclosure

| | Mobility | HOMO | BDE (Anion) |
|---|---|---|---|
| NPB | 8.8 × 10⁻⁴ | 5.4 | / |
| Contrast HT | 6.7 × 10⁻⁵ | 5.37 | / |
| EBL1-1 | 1.4 × 10⁻⁵ | 5.53 | 1.01 |
| EBL1-2 | 1.1 × 10⁻⁵ | 5.48 | 0.85 |
| EBL1-3 | 7.5 × 10⁻⁶ | 5.58 | 0.97 |
| EBL2-1 | 1.1 × 10⁻⁶ | 5.50 | 1.57 |
| EBL2-2 | 1.6 × 10⁻⁶ | 5.46 | 1.53 |
| EBL2-3 | 1.1 × 10⁻⁶ | 5.47 | 1.59 |
| HT-1 | 7.7 × 10⁻⁴ | 5.35 | 1.04 |
| HT-2 | 2.2 × 10⁻⁴ | 5.39 | 1.07 |

TABLE 2
Performance data for devices in the above contrast
embodiments and embodiments of the disclosure

| | | | | Lifetime |
|---|---|---|---|---|
| Device (Hole transport layer/ | | Volt- | Effi- | (LT95@1000 |
| electron blocking layer) | | age | ciency | nit) |
| Contrast | NPB/EBL1-1 | 100% | 100% | 100% |
| embodiment 1 | | | | |
| Contrast | NPB/EBL2-1 | 102% | 79% | 189% |
| embodiment 2 | | | | |
| Contrast | Contrast | 100% | 91% | 208% |
| embodiment 3 | HT/EBL1-1/EBL2-1 | | | |
| Contrast | HT1/EBL2-1/EBL1-1 | 102% | 79% | 112% |
| embodiment 4 | | | | |
| Embodiment 1 | HT1/EBL1-1/EBL2-1 | 99% | 108% | >500% |
| Embodiment 2 | HT1/EBL1-2/EBL2-2 | 100% | 105% | >500% |
| Embodiment 3 | HT1/EBL1-3/EBL2-3 | 98% | 112% | >500% |
| Embodiment 4 | HT2/EBL1-1/EBL2-1 | 99% | 108% | >500% |
| Embodiment 5 | HT1/EBL1-1:EBL2-1 | 98% | 112% | 235% |

It should be noted that when the first electron blocking layer (EBL1) and the second electron blocking layer (EBL2) are used for the electron blocking layer, the sum of the thickness of EBL1 and the thickness of EBL2 remains consistent with that of a single-layer electron blocking layer without increasing material consumption, and the same Mask is used for evaporation, without increasing the cost and time consumption.

As can be seen from contrast embodiments 1-3 and Embodiments 1-4, the voltage, efficiency, and lifetime (as shown in FIG. 6, LT indicates the lifetime) are optimized to varying degrees based on the combinations of the hole transport layer (HT) and the electron blocking layer (EBL) in the disclosure. It can be seen from contrast embodiment 4 and Embodiments 1-4 that the order of the first electron blocking layer (EBL1) and the second electron blocking layer (EBL2) has an important influence on the device performance, and the device performance is optimal when the first electron blocking layer (EBL1) is close to the side of the hole transport layer (HT), and the second electron blocking layer (EBL2) is facing away from the side of the hole transport layer (HT). As can be seen from Embodiments 1-4 and Embodiment 5, the efficiency of the pre-mixed first material (EBL1-1) and second material (EBL2-1) can be improved relative to the contrast embodiments, but the lifetime is improved less.

In summary, the efficiency and lifetime of the blue-light-emitting device employing the device structure, energy level combination, and material combinations designed according to the embodiments of the disclosure are greatly improved, and the voltage (the power consumption is reduced) is reduced.

Based on the same inventive concept, an embodiment of the disclosure also provides a manufacturing method for the above blue-light-emitting device, including:
forming a hole transport layer, an electron blocking layer, and a light-emitting layer which are in stack; where the electron blocking layer includes a first material and a second material, the mobility of the first material is a first mobility, and the mobility of the second material is a second mobility; and the mobility of the hole transport layer is greater than the mobility of the first material, and the mobility of the hole transport layer is greater than the mobility of the second material.

A general structural formula of a material of the hole transport layer is

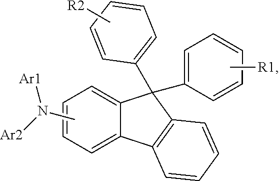

general structural formulae of the first material and the second material are both

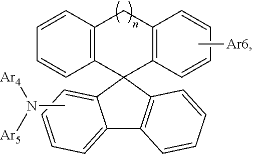

and the first material and the second material have different bond energies.

Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, arylamino with 6 to 39 carbon atoms, cycloalkyl with 3 to 39 carbon atoms, heterocycloalkyl with 3 to 39 carbon atoms, and alkylsilyl with 1 to 39 carbon atoms.

R1 and R2 are independently selected from hydrogen and alkyl with 1 to 39 carbon atoms; and n is 0 or 1.

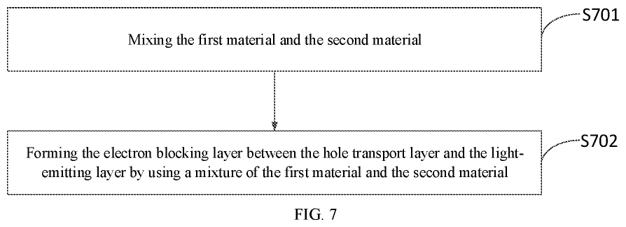

In some embodiments, in the above manufacturing method provided by the embodiment of the disclosure, forming the electron blocking layer 2 as shown in FIG. 2, as shown in FIG. 7, may specifically include the following S701-S702.

S701, mixing the first material and the second material.

S702, manufacturing the electron blocking layer between the hole transport layer and the light-emitting layer by using a mixture of the first material and the second material.

In some embodiments, in the above manufacturing method provided by the embodiment of the disclosure, forming the electron blocking layer 2 as shown in FIG. 3 may specifically include:
forming a first electron blocking layer close to the hole transport layer by using the first material, and forming a second electron blocking layer located between the first electron blocking layer and the light-emitting layer by using the second material.

Specifically, the manufacturing method of film layers in the above blue-light-emitting device includes, but is not limited to, one or more of a spin coating method, an evaporation method, a chemical vapor deposition method, a physical vapor deposition method, a magnetron sputtering method, an ink-jet printing method, an electrojet printing method, and the like.

In one possible embodiment, manufacturing the blue-light-emitting device shown in FIG. 5, taking the condition that the blue-light-emitting device shown in FIG. 5 is of a conventional structure as an example, specifically includes:
forming an anode 4 on a glass substrate, where a material of the anode 4 may be ITO;
forming a hole injection layer (not shown) having a thickness of about 60 nm by vacuum evaporating a 4,4′,4″-tris[2-naphthyl(phenyl)amino]triphenylamine (2-TNATA) film on the anode 4 (the ITO layer) on the glass substrate;
forming a hole transport layer 1 and an electron blocking layer 2 by vacuum evaporating a hole transport material having a thickness of about 100 nm and an electron blocking material having a thickness of about 10 nm sequentially on the hole injection layer;
forming a light-emitting layer 3 on the electron blocking layer 2;
forming a hole blocking layer 5 by vacuum evaporating a hole blocking material having a thickness of about 10 nm on the light-emitting layer 3;
forming an electron transport layer 6 by vacuum evaporating tris(8-quinolineoleate)aluminum (Alq3) having a thickness of about 40 nm on the hole blocking layer 5;
forming an electron injection layer 7 by vacuum evaporating LiF as alkali metal halide having a thickness of about 0.2 nm on the electron transport layer 6; and forming a cathode 8 by evaporation of Al having a thickness of about 150 nm.

It should be noted that the materials and the thicknesses of the film layers used in the manufacturing method are only one of the embodiments of the disclosure, and of course, the materials and the thicknesses of the film layers are not limited thereto.

Based on the same inventive concept, an embodiment of the disclosure also provides a display apparatus, including any one of the blue-light-emitting devices described above.

Specifically, the type of the display apparatus may be any one of display devices such as an organic light-emitting diode (OLED) display device, an in-plane switching (IPS) display device, a twisted nematic (TN) display device, a vertical alignment (VA) display device, electronic paper, a quantum dot light emitting diode (QLED) display device, or a micro LED (μLED) display device, which is not particularly limited in the disclosure.

The display apparatus may be: any product or component with a display function, such as a mobile phone, a tablet computer, a television, a display, a notebook computer, a digital photo frame, and a navigator. It should be understood by those of ordinary skill in the art that the display apparatus should have other essential constituent parts, which is not repeated here and should not be regarded as limitation to the disclosure. Since the principle of solving the problem of the display apparatus is similar to that of the aforementioned blue-light-emitting device, the implementation of the display apparatus can refer to the implementation of the aforementioned blue-light-emitting device, and repetitions are omitted.

According to the above blue-light-emitting device and the manufacturing method therefor, and the display apparatus provided by the embodiments of the disclosure, through the device structure designed according to the embodiments of the disclosure and the material structure characteristics and mobility laws of the hole transport layer and the electron blocking layer in collocation, the performance of the blue-light-emitting device can be greatly improved, and finally the efficiency and lifetime of the blue-light-emitting device are simultaneously improved, and the power consumption is reduced.

Although preferred embodiments of the disclosure have been described, those skilled in the art can make additional changes and modifications to these embodiments once they know the basic inventive concepts. Therefore, the appended claims are intended to be explained as including the preferred embodiments and all changes and modifications falling within the scope of the disclosure.

Apparently, those skilled in the art can make various changes and modifications to the embodiments of the disclosure without departing from the spirit and the scope of the embodiments of the disclosure. Thus, if these changes and transformations of the embodiments of the disclosure fall within the scope of the claims and their equivalents of the disclosure, the disclosure is also intended to include these changes and modifications.

1. A blue-light-emitting device, comprising a hole transport layer, an electron blocking layer and a light-emitting layer which are in stack, wherein
the electron blocking layer comprises a first material and a second material, a mobility of the first material is a first mobility, and a mobility of the second material is a second mobility; and
a mobility of the hole transport layer is greater than the first mobility of the first material, and the mobility of the hole transport layer is greater than the second mobility of the second material; wherein,
a general structural formula of a material of the hole transport layer is 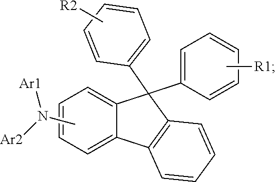
general structural formulae of the first material and the second material are both 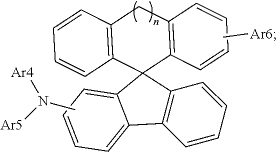
and
the first material and the second material have different bond energies;
wherein Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, arylamino with 6 to 39 carbon atoms, cycloalkyl with 3 to 39 carbon atoms, heterocycloalkyl with 3 to 39 carbon atoms, and alkylsilyl with 1 to 39 carbon atoms;
R1 and R2 are independently selected from hydrogen and alkyl with 1 to 39 carbon atoms; and
n is 0 or 1.

2. The blue-light-emitting device according to claim 1, wherein the electron blocking layer is of a single-layer structure; and
a material of the electron blocking layer is a mixed material of the first material and the second material.

3. The blue-light-emitting device according to claim 1, wherein
the electron blocking layer comprises:
a first electron blocking layer close to the hole transport layer; and
a second electron blocking layer between the first electron blocking layer and the light-emitting layer;
wherein a material of the first electron blocking layer is the first material and a material of the second electron blocking layer is the second material;
wherein,
the first mobility is greater than the second mobility; and
a bond energy of the second material is greater than a bond energy of the first material.

4. The blue-light-emitting device according to claim 2, wherein
a ratio of the mobility of the hole transport layer to the first mobility is greater than 10;
a ratio of the mobility of the hole transport layer to the second mobility is greater than 10; and
a ratio of the first mobility to the second mobility is greater than 1.

5. The blue-light-emitting device according to claim 4, wherein the mobility of the hole transport layer is 1×10⁻⁶ cm²/V·s-9.9×10⁻³ cm²/V·s, the first mobility is 1×10⁻⁸ cm²/V·s-1×10⁻⁴ cm²/V·s, and the second mobility is 1×10⁻⁹ cm²/V·s-1×10⁻⁵ cm²/V·s.

6. The blue-light-emitting device according to claim 2, wherein
a bond energy for positive charge of the first material is greater than or equal to 2.8 eV;
a bond energy for negative charge of the first material is greater than or equal to 0.8 eV;
a bond energy for positive charge of the second material is greater than or equal to 3 eV; and
a bond energy for negative charge of the second material is greater than or equal to 1 eV.

7. The blue-light-emitting device according to claim 1, wherein a HOMO energy level of the hole transport layer is −5.6 eV to −5.2 eV.

8. The blue-light-emitting device according to claim 1, wherein the material of the hole transport layer has a molecular weight greater than or equal to 550.

9. The blue-light-emitting device according to claim 2, wherein a difference between a HOMO energy level of the first material and a HOMO energy level of the second material is less than or equal to 0.2 eV.

10. The blue-light-emitting device according to claim 2, wherein the first material and the second material each have a molecular weight greater than or equal to 450.

11. The blue-light-emitting device according to claim 1 wherein the material of the hole transport layer is

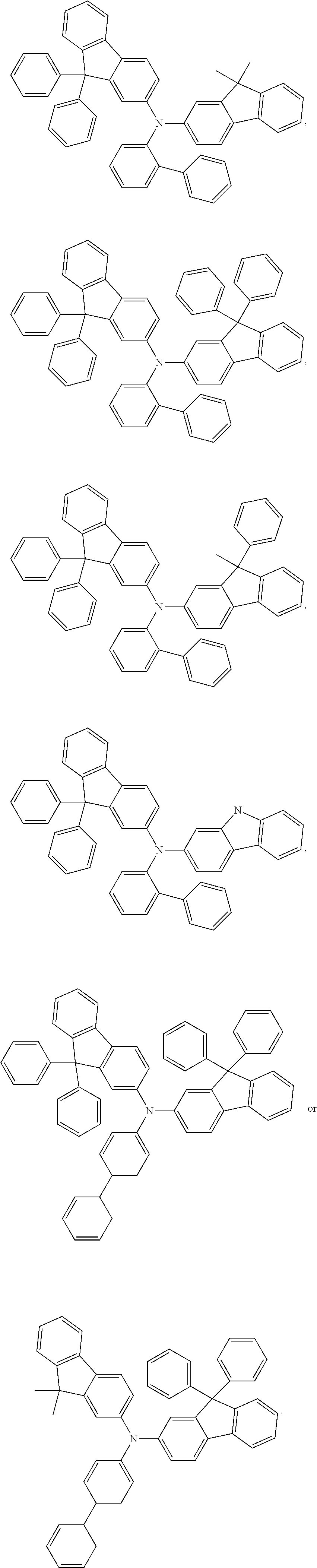

12. The blue-light-emitting device according to claim 3, wherein the first material and the second material are isomers.

13. The blue-light-emitting device according to claim 12, wherein
a structure of the first material is 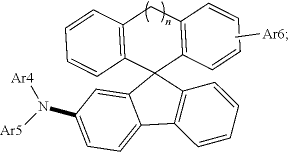
and
a structure of the second material

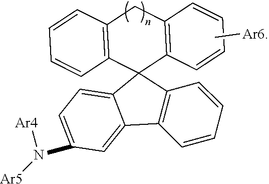

14. The blue-light-emitting device according to claim 12, wherein
the structure of the first material is 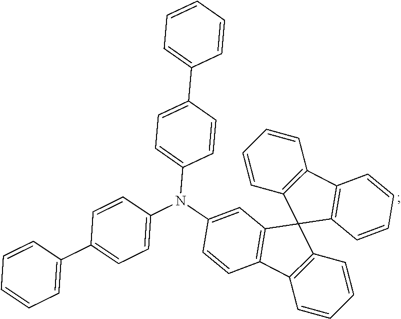 [SMILES: c1ccc(-c2ccc(N(c3ccc(-c4ccccc4)cc3)c3ccc4c(c3)C3(c5ccccc5-c5ccccc53)c3ccccc3-4)cc2)cc1]
and the structure of the second material is 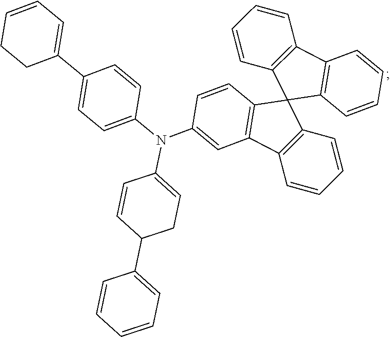 [SMILES: C1=CCCC(c2ccc(N(C3=CCC(c4ccccc4)C=C3)c3ccc4c(c3)-c3ccccc3C43c4ccccc4-c4ccccc43)cc2)=C1]
or
the structure of the first material is 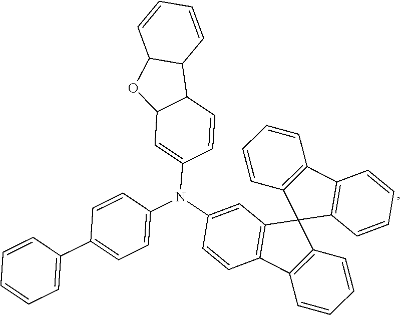 [SMILES: C1=CC2OC3C=C(N(c4ccc(-c5ccccc5)cc4)c4ccc5c(c4)C4(c6ccccc6-c6ccccc64)c4ccccc4-5)C=CC3C2C=C1]
and the structure of the second material is 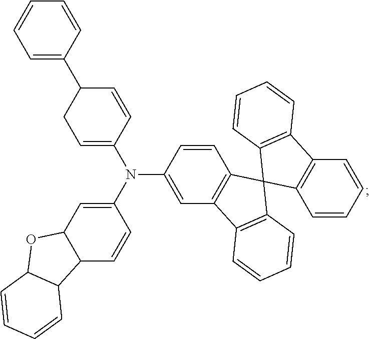 [SMILES: C1=CC2OC3C=C(N(C4=CCC(c5ccccc5)C=C4)c4ccc5c(c4)-c4ccccc4C54c5ccccc5-c5ccccc54)C=CC3C2C=C1]
or
the structure of the first material is 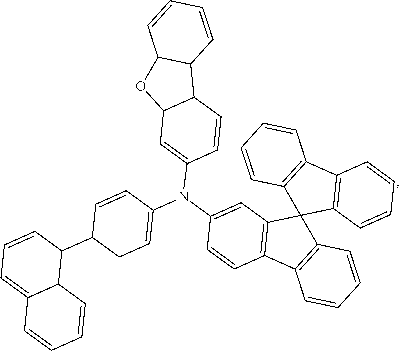 [SMILES: C1=CC2=CC=CC(C3C=CC(N(C4=CC5OC6C=CC=CC6C5C=C4)c4ccc5c(c4)C4(c6ccccc6-c6ccccc64)c4ccccc4-5)=CC3)C2C=C1]
and the structure of the second material is 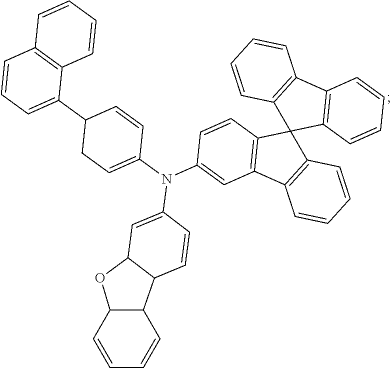 [SMILES: C1=CC2OC3C=C(N(C4=CCC(c5cccc6ccccc56)C=C4)c4ccc5c(c4)-c4ccccc4C54c5ccccc5-c5ccccc54)C=CC3C2C=C1]
or
the structure of the first material is 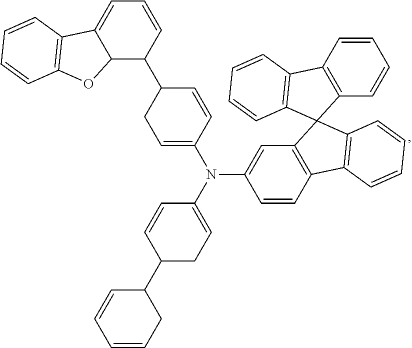 [SMILES: C1=CCC(C2C=CC(N(C3=CCC(C4C=CC=C5c6ccccc6OC54)C=C3)c3ccc4c(c3)C3(c5ccccc5-c5ccccc53)c3ccccc3-4)=CC2)C=C1]
and the structure of the second material is

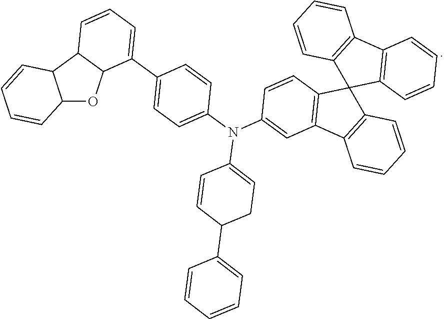 [SMILES: C1=CC2OC3C(c4ccc(N(C5=CCC(c6ccccc6)C=C5)c5ccc6c(c5)-c5ccccc5C65c6ccccc6-c6ccccc65)cc4)=CC=CC3C2C=C1]

15. The blue-light-emitting device according to claim 1, further comprising:
an anode disposed on the side of the hole transport layer facing away from the light-emitting layer;
a hole blocking layer disposed on the side of the light-emitting layer facing away from the hole transport layer;
an electron transport layer disposed on the side of the hole blocking layer facing away from the hole transport layer;
an electron injection layer disposed on the side of the electron transport layer facing away from the hole transport layer; and
a cathode disposed on the side of the electron injection layer facing away from the hole transport layer.

16. A display apparatus, comprising the blue-light-emitting device according to claim 1.

17. A manufacturing method for the blue-light-emitting device according to claim 1, comprising:
forming a hole transport layer, an electron blocking layer, and a light-emitting layer which are in stack;
wherein the electron blocking layer comprises a first material and a second material, a mobility of the first material is a first mobility, and a mobility of the second material is a second mobility; and a mobility of the hole transport layer is greater than the first mobility of the first material, and the mobility of the hole transport layer is greater than the second mobility of the second material;
wherein,
a general structural formula of a material of the hole transport layer is 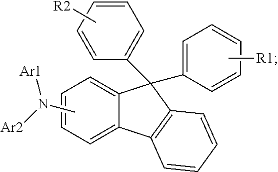
general structural formulae of the first material and the second material are both 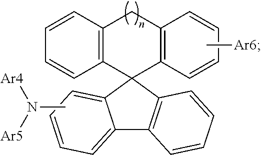
wherein the first material and the second material have different bond energies;
wherein Ar1, Ar2, Ar4, Ar5, and Ar6 are independently selected from: hydrogen, deuterium, halogen, cyano, nitro, alkyl with 1 to 39 carbon atoms, alkenyl with 2 to 39 carbon atoms, alkynyl with 2 to 39 carbon atoms, aryl with 6 to 39 carbon atoms, heteroaryl with 5 to 60 carbon atoms, aryloxy with 6 to 60 carbon atoms, alkoxy with 1 to 39 carbon atoms, arylamino with 6 to 39 carbon atoms, cycloalkyl with 3 to 39 carbon atoms, heterocycloalkyl with 3 to 39 carbon atoms, and alkylsilyl with 1 to 39 carbon atoms;
R1 and R2 are independently selected from hydrogen and alkyl with 1 to 39 carbon atoms; and
n is 0 or 1.

18. The manufacturing method according to claim 17, wherein forming the electron blocking layer comprises:
mixing the first material and the second material; and
forming the electron blocking layer between the hole transport layer and the light-emitting layer by using a mixture of the first material and the second material.

19. The manufacturing method according to claim 17, wherein forming the electron blocking layer comprises:
forming a first electron blocking layer close to the hole transport layer by using the first material; and
forming a second electron blocking layer between the first electron blocking layer and the light-emitting layer by using the second material.
